(19) United States
(12) Patent Application Publication
(10) Pub. No.: US 2012/0018413 A1
(43) Pub. Date: Jan. 26, 2012

(54) METHOD OF HEAT TREATMENT AND/OR INSPECTION OF FUNCTIONAL MECHANICAL PROPERTIES, PARTICULARLY TRANSFORMATION STRAIN AND/OR STRENGTH, OF SHAPE MEMORY ALLOY FILAMENTS AND APPARATUS FOR THE APPLICATION OF THIS METHOD

(76) Inventors: Jan Pilch, Klecany (CZ); Petr Sittner, Praha (CZ)

(21) Appl. No.: 13/262,899

(22) PCT Filed: May 4, 2010
(86) PCT No.: PCT/CZ10/00058

§ 371 Date: Oct. 4, 2011

(30) Foreign Application Priority Data
May 4, 2009 (CZ) PV 2009-279

(51) Int. Cl. H05B 1/00; G01R 27/08; G01N 25/00; G01N 29/11

(52) U.S. Cl. 219/201; 73/599; 324/691; 374/45

(57) ABSTRACT

A method of heat treatment and/or inspection of functional mechanical properties, particularly transformation strain and/or strength, of shape memory alloy filaments and apparatus for the application of this method.

This invention introduces a method and equipment for nonconventional thermo-electro-mechanical treatment of continuous and discontinuous SMA filaments, particularly NiTi, allowing for setting their functional mechanical properties, particularly transformation strain and/or strength, as required by the user. Heat treatment of continuous SMA filaments is realized on an apparatus consisting of respooling system with driving units for feeding and taking spools and at least two electrical contacts allowing conductive for electrical contact of the respooled filament and electric current source. When applying the method, an effective filament temperature is first evaluated from the interpolated experimentally determined dependence of transformation strain and/or strength of the filament achieved by range of heat treatments characterized by various effective filament temperatures and tensile stress. Heat treatment is then performed by supplying the electric power calculated from this effective filament temperature to the segment of the treated SMA filament. Heat treatment can also be performed utilizing on-line control of the supplied electric current in a feedback to the on-line measured filament temperature and/or change of electric resistance before and after the treatment. Compared to currently used conventional heat treatment of SMA filaments in environmental furnace, the filament treated by the present method is exposed to much higher temperatures for much shorter time allowing for efficient, less energy consuming and compact heat treatment of continuous SMA filaments for applications in technical textile production. Functional mechanical properties different from those achievable by conventional heat treatment can be given to the treated SMA filaments. In addition, this invention introduces a method for inspection of the homogeneity of continuous SMA filaments consisting in measurement of the electrical resistance, temperature and/or characteristics of the ultrasonic signal passing through the filament during respooling. The homogeneity of the SMA filament is evaluated as the deviation of the actually measured value of one of these quantities from the expected value. The method is realized on apparatus with respooling system and sensors of the above introduced signals.

A method of heat treatment and/or inspection of functional mechanical properties, particularly transformation strain and/or strength, of shape memory alloy filaments and apparatus for the application of this method.

### TECHNICAL FIELD

This invention concerns a method for heat treatment of shape memory alloy filaments allowing for setting their functional mechanical properties, in particular transformation strain and/or strength, and/or for inspection of their homogeneity and apparatus for the application of this method.

### BACKGROUND ART

Shape memory alloys (SMA) belong to the class of functional engineering materials exhibiting unique thermomechanical properties as superelasticity or shape memory effects. The commercially most successful NiTi alloy is also known under the name Nitinol. NiTi is a metallic alloy having atomic concentration of Ni and Ti element in ratio approximately 1:1 and possibly other solute elements in minor concentration (Cu, Fe, Cr, Hf etc.). As cast or powder metallurgy route prepared ingots of NiTi alloy have to be formed into final form by series of hot working and annealing treatments followed by final cold working and heat treatment. The final products need to have specified shape, typically straight wire, tube or sheet and specified functional mechanical properties, e.g. superelastic properties, utilized in engineering applications. Superelastic NiTi alloys are currently mainly used for production of medical devices and implants, shape memory and actuator elements utilized in robotics, automotive and space industrial applications.

The properties of NiTi are mainly set by careful selection of the chemical composition. Nevertheless, the whole technological route is important, particularly the final cold working and subsequent heat treatment in an environmental furnace or salt bath has the most decisive influence on their final functional mechanical properties. This is the subject of e.g. patents JP62083455 or JP62083455.

At present, manufacturing of hybrid fabrics with integrated thin NiTi filaments is being seriously considered for production of medical and other technical textile products. It appears that an opportunity to set functional mechanical properties of long continuous filaments according to requirements of the textile manufacturer becomes essential for the further spread of the hybrid NiTi textile technology. It concerns particularly the adjustment of strength, elastic modulus, transformation stress, transformation strain and stability of cyclic deformation and fatigue properties of the filament. Conventionally, continuous NiTi filaments are presently heat treated in tubular electrical furnace several meters long with carefully set temperature filled with inert gas atmosphere. The filament moves through the center of the furnace with a controlled speed of about 1 m/min., while being exposed to relatively small constant tensile force. After such treatment, the SMA filaments are supplied to the customers on spools and denoted as “straight annealed”. An example of such heat treatment method is known e.g. from U.S. Pat. No. 3,953,253. It describes a particular heat treatment of NiTi filament aimed to optimize its strength while maintaining its functional mechanical properties. The temperature in the furnace is set just above the temperature evaluated by previous electrical resistance measurements as temperature at which electric resistance of the wire starts to decrease upon heating.

Main disadvantage of the heat treatment in long environmental furnace for textile applications is the relatively slow speed by which the filament has to move through the furnace. This slow speed does not allow for efficient heat treatment of the large quantities of the SMA filament. Another disadvantage of the conventional heat treatment is that it is not possible to set reliably functional mechanical properties of filaments, the microstructure of which is not known. In this case, it is necessary to perform a series of extremely time consuming heat treatment experiments with subsequent thermomechanical testing, the result of which provide relationship between the functional properties of the filaments and parameters of the heat treatment, particularly the furnace temperature, the time of annealing and the filament tensile stress. Finally, the large dimension of the environmental furnace, makes its utilization for textile processing very inconvenient. As a result, the heat treatment of continuous SMA filaments is currently performed solely by SMA producers and the end users have only very limited opportunity to set or modify the functional mechanical properties of the SMA filaments purchased from SMA producer.

SMA producers also offer continuous SMA filaments in a material state after cold work, in which the filaments do not have any functional properties, i.e. transformation strain, stress etc. These filaments are denoted as “hard”, “cold worked” or “as drawn”. They show just elastic mechanical response, nevertheless, they still may have mutually very different material states, particularly to microstructure, texture etc., depending on the hot work and annealing history they were exposed to. Applying the same final heat treatment to the several SMA filaments having different microstructures will result in different functional mechanical properties of the treated filaments, particularly transformation strain and strength. Conventionally, heat treatment of short NiTi wire segments is performed by engineers and material scientists in environmental laboratory furnaces at temperatures T>400° C. and annealing times longer than 10 minutes.

SMA filaments are being also frequently heated by electric current with the aim to actively utilize its already set functional properties. The supplied electric power in this case, however, must be limited so that the functional mechanical properties, particularly transformation strain and strength, do not change. At the same time, the memorized shape of the SMA element must not be affected by the supplied electric power. Heating the SMA filament by electric current with the aim to utilize its functional behavior is described for example in patent application WO2006/105588.

Patent applications GB2441589 or EP1516936 deal with heat treatment of short NiTi wires embedded in composite textiles or SMA-polymer composites, which is also performed by electric current. The goal of this treatment, however, is not to set the functional properties of the filament to the user preset values but only to adjust its shape or material state to the host textile structure.

No SMA filament treatment method, which would allow for simultaneous setting of the functional mechanical properties, particularly the transformation strain and strength, and perform inspection of the homogeneity of the filament properties, was found in the literature search. In addition to the homogeneity of the set functional properties along the length of the filament, the SMA filaments may contain cracks, voids, oxide or carbide particles. The inhomogeneity of functional properties would have adverse effect on filament use and the inclusions may cause early damage or fracture of the filaments. Safe application of continuous NiTi filaments in engineering applications requires inspection of the homogeneity of the filament properties and occurrence of inhomogeneities.

This invention introduces a new nonconventional method for heat treatment of SMA filaments allowing for a quick and precise setting of their functional mechanical properties as desired by the user. Heat treatment of continuous SMA filaments optionally features on line control of the set functional properties which assures their homogeneity. Heat treatment of SMA filaments using this method is relatively inexpensive, less energy consuming and the apparatus is more compact compared to the equipment currently used by SMA producers for the same purpose. Hence it better suits the current needs in hybrid NiTi textile production.

### DISCLOSURE OF THE INVENTION

The heat treatment method proposed in this invention basically eliminates the above pointed out shortcomings of the conventional heat treatment of SMA filaments in environmental furnace while allowing the user to set the functional mechanical properties of metallic SMA filaments, particularly transformation strain and strength, as he requires. The method consists in taking a sample of the filament, the functional mechanical properties of which, particularly transformation strain and/or strength, are to be set and performing on it a series of thermomechanical experiments from which a dependence between transformation strain and/or strength of the filament and maximum filament temperature achieved by Joule heating under selected tensile stress is established. The maximum filament temperature needed to set the required transformation strain and/or strength of the filament is determined from this dependence. Following that, the electric power needed to reach this maximum filament temperature by Joule heating is calculated. The filament is then subsequently exposed to electric current for a time corresponding to the calculated electric power while applying the selected tensile stress.

In this way, the functional mechanical properties of the SMA filament, particularly transformation strain and strength, which correspond to specific microstructure in the filament (size of polygonized cells, recrystallized grains, dislocation defects density, internal stress etc.) are set. Such an extremely precise adjustment of the functional mechanical properties of the SMA filaments is not possible if the heat treatment is being performed in conventional environmental furnace without an extremely time consuming series of heat treatment experiments and subsequent tensile tests. The filament microstructure is not being set only due to its exposition to high temperature but also due to the direct action of electric current. Consequently, SMA filaments with different functional properties compared to those resulting from the application of the conventional heat treatment method known from literature can be prepared.

Alternatively, the method for the heat treatment of shape memory alloy filaments consists in that a sample of the filament, the functional mechanical properties of which, particularly transformation strain and/or strength, are to be set is taken and a dependence between transformation strain and/or strength of this filament and maximum filament temperature achieved by Joule heating under selected tensile stress is established. Maximum filament temperature needed to set the required transformation strain and/or strength is determined from this dependence. The filament is subsequently exposed to electric current controlled in a feedback loop so that the SMA filament temperature corresponds to the determined value for a given tensile stress in the filament.

Controlling the supplied electric power in the feedback loop based on the filament temperature allows skipping the electric power calculation and assures homogeneity of the functional mechanical properties of the treated filament.

Alternatively, the method for the heat treatment of shape memory alloy filaments consists in that a sample of the filament, the functional mechanical properties of which, particularly transformation strain and/or strength, are to be set is taken and a dependence between transformation strain and/or strength of this filament and change of the electric resistance of the filament before and after treatment under controlled tensile stress is established. The change of the electric resistance of the filament before and after treatment corresponding to the desired transformation strain and/or strength is determined from this dependence. The filament is subsequently exposed to electric current controlled in a feedback loop so that the change of the electric resistance of the filament before and after treatment corresponds to the set value while applying the selected tensile stress. Controlling the supplied electric current in a feedback loop based on the electric resistance of the filament after treatment allows skipping the electric power calculation and/or measurement of the filament temperature.

In this way, a precisely controlled setting of functional mechanical properties of the SMA filament, particularly transformation strain and strength, is achieved. The electric resistance of the filament evaluated at specific temperature and tensile stress corresponds very well to its superelastic and/or shape memory properties. For a particular as drawn SMA filament, the values of relative change of the electric resistance measured at specific temperature and tensile stress can be associated with particular filament microstructure and corresponding functional mechanical properties, particularly transformation strain and strength. Thermo-electro-mechanical treatment of continuous filaments in a feedback loop based on the electric resistance of the filament after treatment moreover eliminates the danger of random changes of the process parameters and related undesired variations of properties of continuous filaments for textile production.

It is beneficial if the stress in the filament due to the applied tensile force is larger than 600 MPa, and simultaneously, the maximum filament temperature achieved in the treatment is smaller than 300° C.

The combination of large tensile stress and low maximum filament temperature will be used particularly for treatment of already partially treated SMA filaments (—i.e. filaments already exhibiting functional mechanical properties) with the goal to give them new shape without modifying their functional properties, particularly to transformation strain and/or strength. At the same time, new shape of the filament will be set at relatively low temperature of the treated filament. This is of major importance for the heat treatment of NiTi filaments already integrated in hybrid NiTi textiles which are not capable to withstand the excessively high temperatures in environmental furnace since the adjoining textile filaments would be damaged. Even if this low temperature heat treatment seems to be just a slight modification of the above introduced heat treatment consisting in that it is performed at low temperatures and high tensile stress, it is by its nature a completely new and in the literature yet not described way of thermomechanical treatment of SMA filaments, which relies on controlled plastic deformation within the stress induced martensite phase, which is not taking place in the treatment of cold worked SMA filaments.

It is beneficial if the supplied electric current and/or tensile stress vary periodically in time during the treatment in a controlled manner.

In this way, it is possible to prepare filaments with periodically varying functional mechanical properties with the period from millimeters to kilometers. It is known from the literature, that it is possible to prepare SMA filaments having a gradient of properties along its length using an environmental furnace with temperature gradient. The hereabout described method has many advantages over this method, for example, preparation of arbitrarily long SMA filaments with gradient of functional mechanical properties and/or with extremely small period of the variation of the functional mechanical properties. It is also very beneficial to prepare SMA filaments having periodically distributed segments, where the filaments remain elastic. This is utilized for example for preparation of short SMA filaments for actuator applications, where is it desired that the part of the actuator wire inserted into grips does not show any functional mechanical properties.

It is beneficial if the time of the action of the supplied electric current is smaller than 100 ms. In this way special conditions are achieved under which the filament is heated for a very short time only and the heat transfer from the filament to its environment is significantly limited. This is of importance in case of shape setting the filaments. If using times larger than 100 ms, the maximum filament temperature is locally lower in places of contacts between the filament and shaping elements due to the heat transfer. This leads to the undesired gradient of functional mechanical properties. Using extremely short heating time under 10 microseconds, this disadvantage can be completely eliminated.

The heat treatment of SMA filaments using the above introduced method is realized on an apparatus consisting at least from the filament supply unit and the filament taking unit, at least two contacts of the electric current source establishing electrical contact with spooled filament, electric current source and filament tensile stress control element. The electric current source is linked to the said electrical contacts by lead wires. The filament is guided from the filament supply unit over the said contacts and the filament tensile stress control element to the filament taking unit. The filament between the contacts is beneficially placed in protecting inert gas atmosphere.

As already mentioned, using the thermo-electro-mechanical treatment of the filaments on this apparatus, it is possible to prepare filaments having functional mechanical properties unachievable via conventional heat treatment in environmental furnace—e.g. having small stress hysteresis, linear dependence of electrical resistance on strain, improved fatigue properties etc. This apparatus allows to heat treat SMA filaments at much higher respooling speed (hundreds of m/min) compared to the speed used in conventional straight annealing treatment in tubular environmental furnace (˜1 m/min). The apparatus is relatively inexpensive, less energy demanding and mainly more compact compared to the currently used equipment. The compactness of the equipment is of essential importance for its wide use in textile production.

It is beneficial if the filament supply unit is the feeding spool and the filament taking unit is the taking spool with driving units and that the apparatus further contains a temperature sensor placed between two electrical contacts of the electric current source, measuring and control unit to which the temperature sensor, filament tensile stress control element and electric current source are linked. The measuring and control unit is beneficially connected to the driving units of the feeding spool and taking spool.

Through the regulation of the maximum filament temperature in the feedback loop based on the reading of the temperature sensor, it is possible to control the supplied electric power so that the obtained functional mechanical properties, particularly the transformation strain and stress, are constant along the length of the treated SMA filament. The apparatus operated with on line feedback control based on the reading of the temperature sensor eliminates the danger of unwanted variations of the functional properties of continuous SMA filaments treated for textile applications.

It is beneficial if the filament supply unit is the feeding spool and the filament taking unit is the taking spool with driving units and that the apparatus further contains two additional contacts for measurement of electrical resistance of untreated filament which are placed before the contacts of the electric current source establishing electrical contacts with the spooled filament and two additional contacts for measurement of electrical resistance of treated filament which are placed after the contacts of the electric current source establishing electrical contacts with the spooled filament. The apparatus further contains measuring and control unit connected to the electrical contacts for measurement of electrical resistance of untreated and treated filament, filament tensile stress control element and electric current source. The measuring and control unit is beneficially connected to the driving units of the feeding spool and taking spool. The apparatus also beneficially contains a cooling system.

Superelastic and shape memory properties of the SMA filaments for textile applications have to be constant along the filament length of several kilometers. This is possible to achieve only if the microstructure of the incoming as drawn filament is constant. Even if this is commonly guaranteed by the suppliers of the as drawn SMA filaments and mostly it is so, the risk of severe consequences of the possible occurrence of inhomogeneities within the incoming filament is relatively high, particularly for medical textiles. The apparatus operated with on line feedback control loop using the electric resistance of the incoming and treated parts of the SMA filament eliminates the danger of unwanted variations of the functional properties of continuous SMA filaments treated for textile applications.

It is beneficial if the filament is guided between the electrical contacts of the electric current source through a filament shaping element, for example an electrically nonconductive screw and further the filament is guided from the filament shaping element to the taking spool with driving unit.

This modification of the apparatus is used when it is desired to prepare SMA filaments with characteristic shape—e.g. serpentine or helical springs. The method thus allows for preparing continuous shape set SMA filaments with desired shape and functional mechanical properties, particularly transformation strain and strength.

The heat treatment of relatively short discontinuous SMA filaments using above introduced method is realized on an apparatus consisting of two conducting filament grips, electric current source, system for control of the tensile stress or tensile strain in the filament connected to one of the filament grips or directly to the filament. The electric current source is connected with filament grips. The apparatus beneficially contains measuring and control unit connected with the electric current source.

Using the apparatus for heat treatment of discontinuous SMA filaments, it is possible to realize stress-strain-temperature conditions in the treated SMA filaments which can be very different from those achieved with the apparatus for heat treatment of continuous filaments. Consequently, SMA filaments with different functional mechanical properties, particularly transformation strain and strength, can be prepared using this apparatus. The apparatus is at the same time used for evaluation of functional mechanical properties of filaments, particularly transformation strain and strength, right after the heat treatment.

It is beneficial if the apparatus further contains a shaping element, for example configurable set of pins, textile or composite structure, and that the filament between the conducting filament grips is guided through this additional shaping element.

This set up is used for heat treatment of NiTi filaments already integrated in hybrid textiles or composites. Application of very short pulses is essential if it is desired to prepare properly shape set short SMA filaments having homogeneous functional mechanical properties along its length.

The invention further introduces a method of the inspection of the homogeneity of functional mechanical properties of continuous SMA filaments, particularly to transformation strain and/or strength. This method consists in measurement of at least one of the following quantities of the treated filament: electrical resistance, temperature, characteristics of the passing through ultrasonic signal, for example attenuation. The filament homogeneity is subsequently evaluated as deviation of the measured value from the expected value of that quantity, for example average value. A record of inhomogeneity is assigned to the position in the filament, where it was detected based on the magnitude of this deviation. This record is memorized by the measuring and control unit, optionally including the record of the position of the detected inhomogeneity. This is beneficially used for example in manufacturing medical NiTi textiles, where inspection of homogeneity of NiTi filaments prior its textile processing is desired.

This method is realized on an apparatus for performing heat treatment and/or inspection of homogeneity of SMA filaments. The apparatus further comprises at least one of the following components, at least two contacts for measurement of electrical resistance of treated filament establishing conducting electrical contacts with spooled filament which are connected to the measuring and control unit or ultrasound source and evaluation unit linked to the ultrasound exciter and to the ultrasound sensor and to the measuring and control unit or temperature sensor connected to the measuring and control unit.

Homogeneity of long continuous SMA filaments can be inspected using this apparatus. When the system, during respooling of continuous SMA filaments, detects a deviation of electric resistance and/or ultrasound propagation characteristics and/or temperature from their expected values, it saves information about the position in the filament where it was detected as well as about the magnitude of the deviation. The system may also terminate the respooling process if this is desired. This information is utilized during further textile processing of this SMA filament. The inspection also eliminates the danger of using a damaged SMA filament containing large oxide or carbide particles, voids, cracks in e.g. medical textile manufacturing.

Filament is understood as the long thin element made from shape memory alloy having circular, prism, polygonal or other cross section shape, including flat strips (ribbons) and tubes.

Shape memory alloy is a metallic alloy exhibiting superelastic and/or shape memory functional thermomechanical properties.

Superelasticity is the property of shape memory alloy consisting in ability to undergo large reversible deformation at constant temperature due to the stress induced martensitic phase transformation.

Shape memory effect is understood as the property of shape memory alloy consisting in that it can be deformed in low temperature martensite state and recover its memorized parent austenite shape upon heating above the austenite finish temperature.

Functional mechanical properties of SMA filaments are understood to be mainly but not only superelasticity and shape memory effects, characterized in the first approximation by the transformation strain and strength of the filament measured in tension. Furthermore, the properties may be characterized by other parameters evaluated from thermomechanical tests as transformation temperatures, elastic moduli of the austenite and martensite phases, accumulated plastic strain during cyclic tensile loading, stress hysteresis in tensile tests, presence of R-phase etc.

Joule heating is understood as a heating of metallic filament by electric current.

Effective temperature Tₚ is understood as the maximum filament temperature which would be achieved by Joule heating considering heat transfer to the air environment. Real temperature of the filament can be slightly different due to the approximations adopted in calculation of the Tₚ concerning for example heat transfer from the filament to the air environment, latent heats of the phase transformations or heats due to microstructure changes in the treated filament.

### FIGURES

The present invention will become more fully understood from the detailed description of preferred examples wherein the drawings listed below are used.

FIG. 1 The apparatus for the heat treatment of continuous SMA filaments.

FIG. 2 The apparatus for the heat treatment of continuous SMA filaments with measurement of filament temperature

FIG. 3 The apparatus for the heat treatment of continuous SMA filaments with measurement of electric resistance of the filament

FIG. 4 The apparatus for the heat treatment of continuous SMA filaments with shaping element

FIG. 5 The apparatus for the heat treatment of discontinuous SMA filaments

FIG. 6 The apparatus for the heat treatment of discontinuous SMA filaments with shaping element

FIG. 7 An apparatus for inspection of the homogeneity of continuous SMA filaments

FIG. 8 Experimentally determined dependence of transformation strain Eₘₜᵣ on the effective temperature Tₚ of the treatment used in example 1

FIG. 9 Tensile stress-strain curves of the filament at room temperature prior and after the heat treatment in example 1

FIG. 10 Experimentally determined dependence of transformation strain Eₘₜᵣ on the effective temperature Tₚ of the treatment used in example 2

FIG. 11 Tensile stress-strain curves of the filament at room temperature prior and after the heat treatment in example 2

FIG. 12 Experimentally determined variation of the electric resistance of the filament during heat treatment of discontinuous SMA filaments in example 3

FIG. 13 Tensile stress-strain curves of the filament at room temperature after heat treatment in example 3

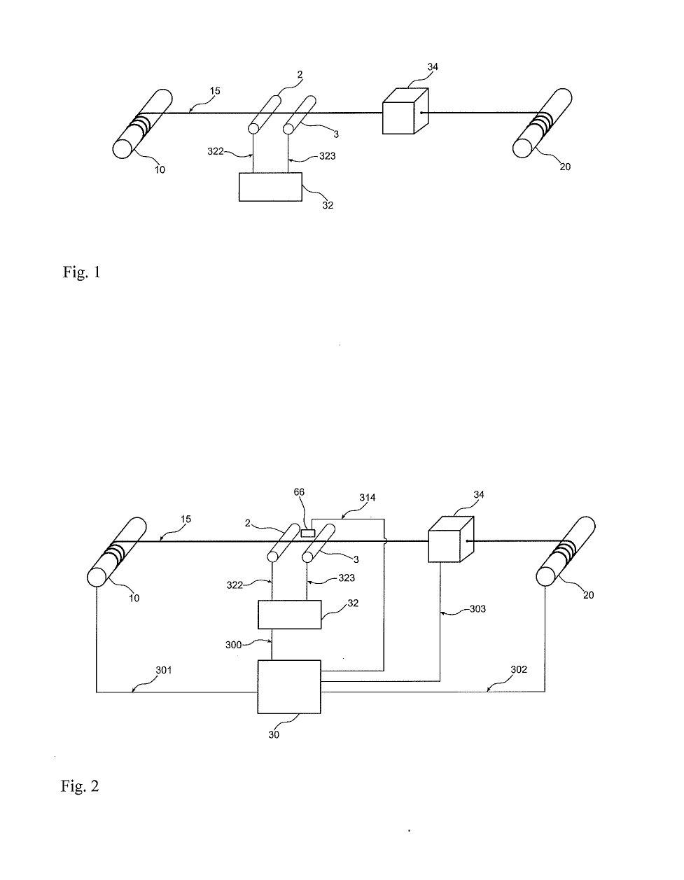

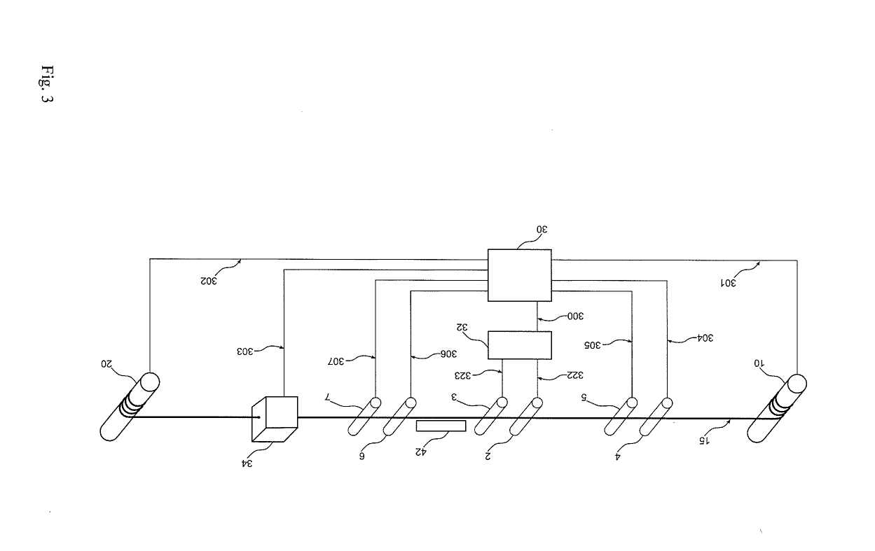

### EXAMPLES

### Used Symbols

C—heat capacity of the filament [J·K⁻¹]
h—heat transfer coefficient between filament (segment between contacts 2 and 3, respectively 84 a 85) and neighboring air atmosphere [W/(m²·K)]
A—filament surface (segment between contacts 2 and 3, respectively 84 a 85) [m²]
Tₑₓₜ—environmental temperature [° C.]
l_{E}—length of the treated filament (segment between contacts 2 and 3, respectively 84 a 85) [m]
vₘ—respooling speed of the treated continuous filament [m·s⁻¹]
σ_{w}—tensile stress in the treated continuous filament [MPa]
P—electric power supplied to the filament (segment between contacts 2 and 3, respectively 84 a 85) [W]
Tₚ—effective filament temperature [° C.]
lₘₜᵣ—length of the treated filament (segment between contacts 2 and 3, respectively 84 a 85) [m]
Eₘₜᵣ—transformation strain—recoverable inelastic strain determined from tensile stress-strain curve at room temperature T₀=22° C. [%] (Initial length of the filament is defined as a the length of the filament measured at temperature T₀=22° C. after cooling from temperature
Tₐ>TAF with no external stress)
T_{Af}—minimal temperature of the heated filament at which the reverse martensitic transformation from the martensite phase to austenite phase finishes [° C.]
tₐ—the time for which the filament (segment of the continuous filament between contacts 2 and 3) is exposed to the action of the electric current_[s]
tₚₐ—the time the filament (discontinuous segment between contacts 84 and 85) is exposed to the action of the electric current_[s]

### Chemical Composition of the SMA Filament Used in Examples

| Element | Weight % |
|---|---|
| Nickel | 54.5-57.0 |
| Titanium | Balance till 100% |
| Carbon | <0.05 |
| Cobalt | <0.05 |
| Copper | <0.01 |
| Chromium | <0.01 |
| Hydrogen | <0.005 |
| Iron | <0.03 |
| Niobium | <0.025 |
| Oxygen | <0.05 |
| Other elements | <0.1 |
| Total amount of all solute elements | <0.25 |
| except of nickel and titanium | |

### Example 1

FIG. 1 shows a schema of the apparatus for the heat treatment of continuous SMA filaments. The filament 15 is respooled from the feeding spool 10 to the taking spool 20. The filament tensile stress control element 34 maintains the desired tensile stress in the filament. The filament is guided first over contact 2 and then 3. Both contacts are connected with the electric current source 32.

Since the filament 15 is typically very thin (˜0.1 mm) and its exposure to electric current is short (˜0.1 s), the actual filament temperature can not be reliably measured. Therefore, it is calculated using the following equation

$$\frac{d}{d t} ( {T}_{p} ( t ) \cdot C ) = P - h \cdot A \cdot ( {T}_{p} ( t ) - {T}_{ext} ) ; {T}_{p} ( 0 ) = {T}_{ext}$$

Left side of the equation evaluates the heat accumulated by the filament in a unit time. The right side describes the difference between the heat supplied to the filament through the Joule heating and the heat transfer from the filament to the air environment per unit time. The time tₐ the filament is exposed to the action of the electric current is calculated as

tₐ=l_{E}/v_{w}.

Prior starting the heat treatment, the user selects desired value of the transformation strain and/or strength he wants to set the filament to. From the interpolated dependence of the transformation strain and/or strength of the filament achieved while using various effective filament temperatures Tₚ, the user determines the desired magnitude of the effective temperature Tₚ and calculates corresponding electric power P for time tₒ using the heat equation. Hence the electric current passing through the respooled filament between contacts 2 and 3 has such value that the filament is heated by the electric power P.

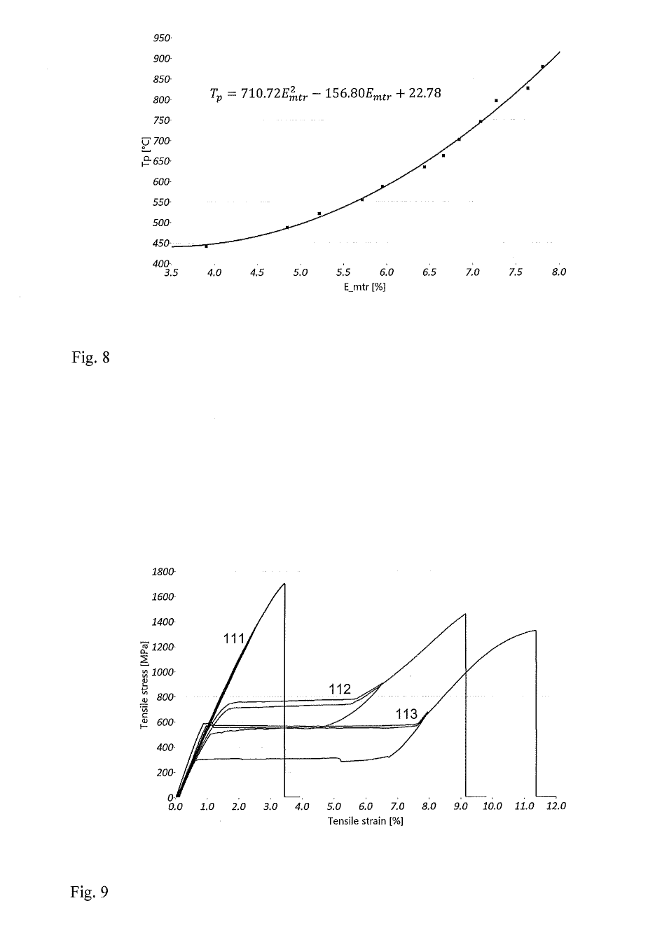

In this example, a NiTi filament of diameter 0.1 mm, having final cold work 40% was used. The curve 111 in FIG. 9 shows its stress-strain response in tensile test at room temperature. The desired values of tensile strain Eₘₜᵣ were 5.7% and 7.6%, respectively. Following the above described method, values of effective temperatures Tₚ=557.1° C. and Tₚ=834.9° C. were determined from FIG. 8. Corresponding values of electric power calculated using the heat equation are P=1.7045 W and P=2.5893 W, respectively. The filament was then respooled with a speed v_{w}=51.3 mm/s under constant tensile stress σ_{w}=110 MPa. The length of the treated filament between the contacts 2 and 3 was 40 mm. The tensile stress-strain curve representing the functional mechanical behavior of the filament (FIG. 9) has changed from the curve 111 representing the cold work filament to the curves 112 and 113 representing the filaments treated using electric power P=1.7045 W and P=2.5893 W, respectively. FIG. 9 documents that using the above described heat treatment method, the filament has acquired functional mechanical properties characterized by the desired value of transformation strain. These functional mechanical properties were constant along the length of the filament.

In this example, the transformation strain Eₘₜᵣ was selected as the desired parameter characterizing the functional mechanical properties of the treated SMA filament. Following the same approach, it is possible to heat treat the filament so that desired values of other parameters characterizing its functional mechanical properties are achieved—e.g. strength, cyclic accumulated plastic strain, stress hysteresis in tensile test etc.

### Example 2

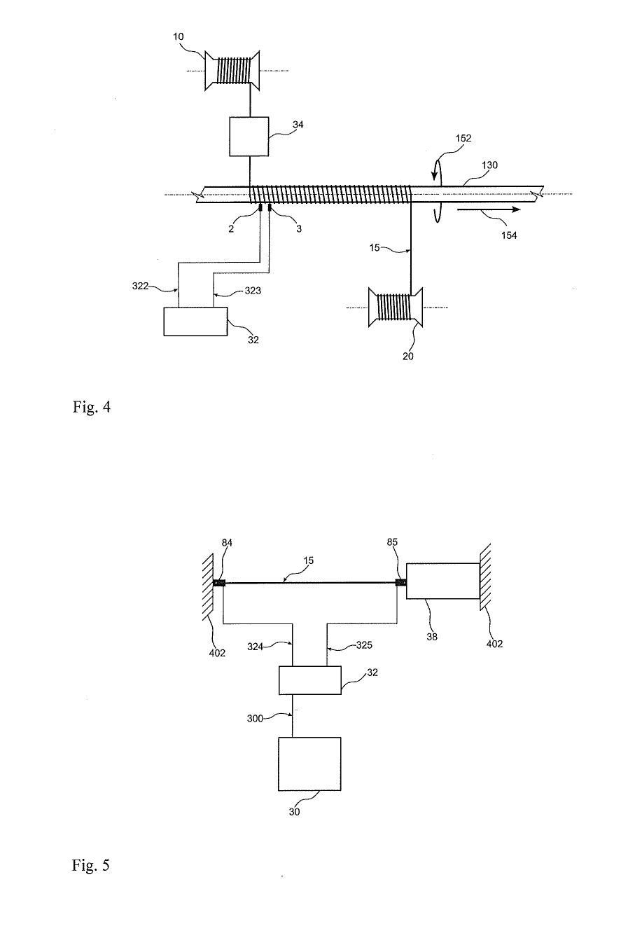

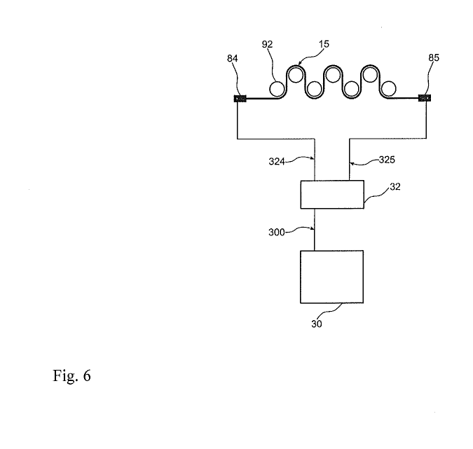

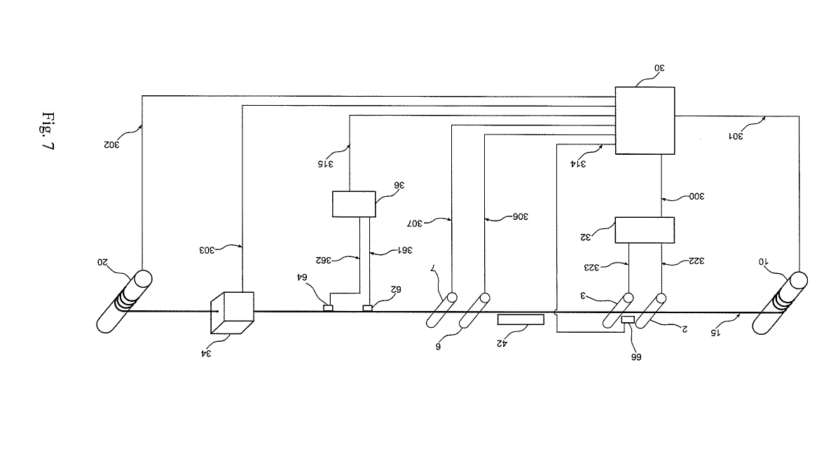

In the previous example 1, we have described the heat treatment of continuous SMA filaments. In this preferred example 2, the heat treatment of short segments of SMA filaments using the apparatus for the heat treatment of discontinuous SMA filaments (FIG. 5) is described. Filament segment is mounted into the grips 84 and 85 which are connected to the electric current source 32. System for control of the tensile stress or tensile strain in the filament 38 connected with one of the grips 84 or 85 allows controlling either tensile strain or tensile stress in the filament in time. The time tₐ the filament is exposed to the action of the electric current can be selected arbitrarily, however, its value affects the homogeneity of temperature distribution and consequently the homogeneity of microstructure in the treated filament. When longer times tₐ are selected, there are gradients of temperature from the filament core towards its surface as well as along the length of the filament from its center towards the parts located in the grips or near contacts with shaping elements (FIG. 6).

Similarly as in the preferred example 1, the user first selects the desired value of transformation strain and/or strength of the treated filament. From the interpolated dependence of the transformation strain and/or strength of the filament achieved while using various effective filament temperatures Tₚ, the user determines the desired magnitude of the effective temperature Tₚ and calculates the corresponding electric power P for time tₐ using the heat equation. The SMA filament is then exposed to electric current pulse generated by the electric current source 32 which corresponds to calculated parameters P for time tₐ. In this way, the filament segment having functional mechanical parameters characterized by the desired value of transformation strain and/or strength is prepared.

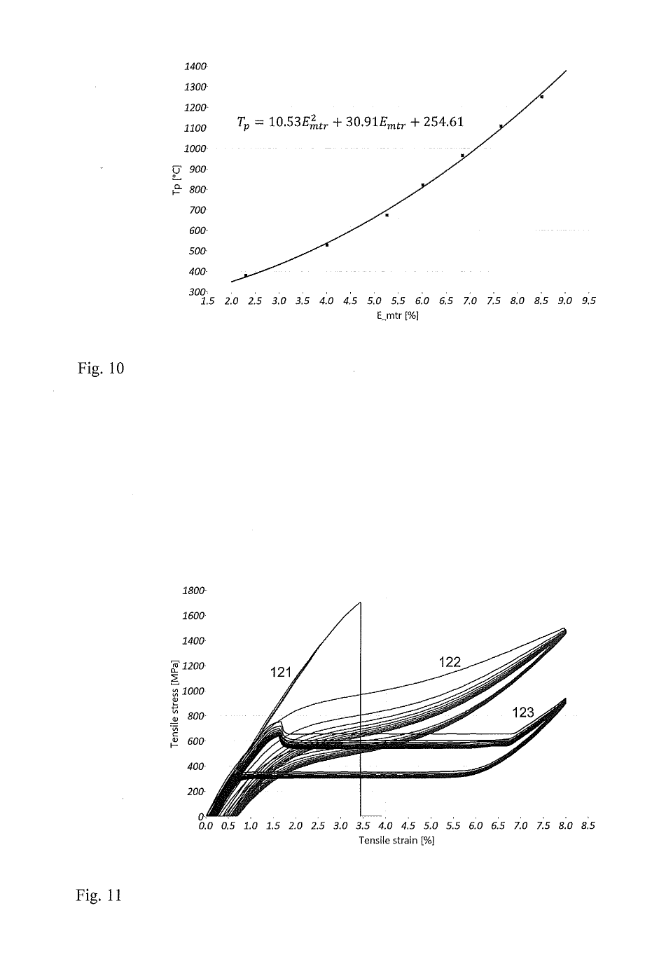

In this example, NiTi filament of diameter 0.1 mm, having final cold work 40% was used. The curve 121 in FIG. 11 shows its stress-strain response in the tensile test at room temperature. The desired values of tensile strain Eₘₜᵣ were 5.3% and 6.8%, respectively. Following above described method, values of effective temperatures Tₚ=657.1° C. and Tₚ=964.5° C. were determined from FIG. 10. Corresponding values of electric power calculated using the heat equation are P=35.87 W and P=53.23 W, respectively. The time the filament is exposed to the action of the electric current was selected as tₐ=0.015 s. The length of the treated filament segment between the grips 84 and 85 was 50 mm. The tensile stress-strain curve representing the functional mechanical behavior of the filament (FIG. 11) has changed from the curve 121 representing the cold worked filament to the curves 122 and 123 representing the filaments treated using electric power P=35.87 W and P=53.23 W, respectively. FIG. 11 documents that using the above described method of heat treatment, the SMA filament has acquired functional mechanical properties characterized by the desired value of transformation strain. The functional mechanical properties were constant along the length of the filament segment.

In this example, the transformation strain Eₘₜᵣ was selected as the desired parameter characterizing the functional mechanical properties of the treated filament. Following the same approach, it is possible to heat treat SMA filaments so that desired values of other parameters characterizing their functional mechanical properties are achieved—e.g. strength, cyclic accumulated plastic strain, stress hysteresis in tensile test etc. Also, a simple electric power pulse P=const in time interval <0, tₐ> was used. It is beneficial to use electric power pulses P=P(t) (supplied electric power carefully controlled in time).

### Example 3

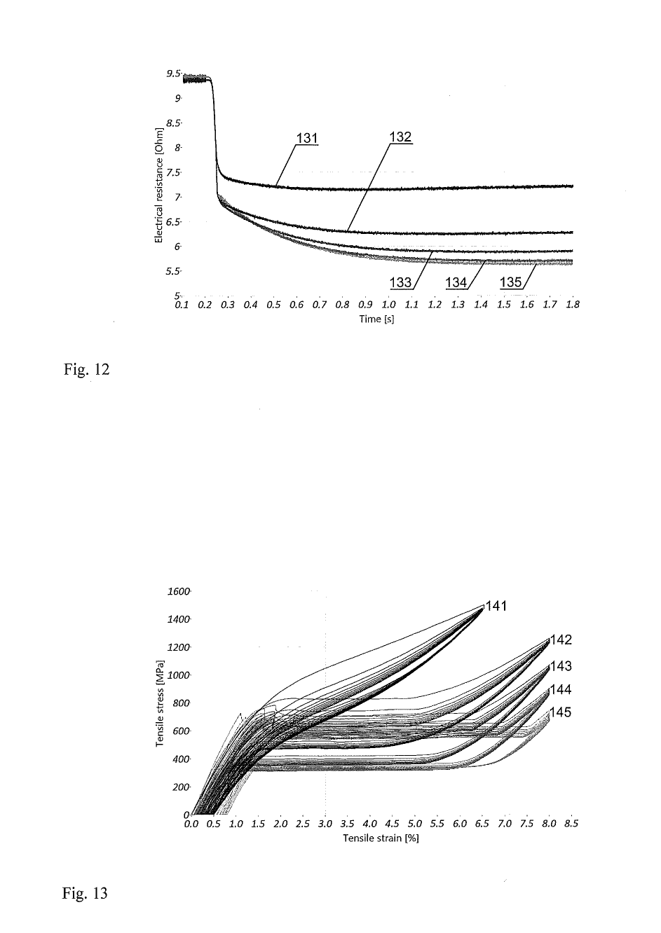

FIG. 3 shows schema of the apparatus for the heat treatment of continuous SMA filaments which uses, additionally to the apparatus presented in preferred example 1, an on line feedback control of the process according to the electric resistance of the treated filament. In this example, the knowledge of the change of the electric resistance of the filament during the heat treatment is actively utilized. FIG. 12 shows 5 experimentally recorded evolutions of the electric resistance during the heat treatment of discontinuous SMA filaments for constant supplied electric power P and various times tₐ for which the filament is exposed to the action of the electric current: curve 131—tₐ=1 ms; curve 132—tₐ=6 ms; curve 133—tₐ=11 ms; curve 134—tₐ=16 ms; curve 135—tₐ=21 ms. FIG. 13 shows corresponding tensile stress-strain curves (10 cycles at room temperature) representing the achieved functional mechanical properties of the treated filament. It is seen from FIG. 12 that the electric resistance values of the SMA filament after each individual heat treatment are mutually significantly different. Their functional mechanical properties are different as well (FIG. 13).

Knowledge of the relationship between of the electric resistance change of the filament during the heat treatment and the selected parameter characterizing the functional mechanical properties of the filament (e.g. transformation strain Eₘₜᵣ) is used when applying the method using the apparatus for the heat treatment of continuous SMA filaments shown in FIG. 3. The electric resistance of the filament is measured before the treatment between contact 4 and 5 and after the treatment between contacts 6 and 7 at defined environmental temperature and tensile stress. The functional mechanical properties of the filament are adjusted by electric current treatment between contacts 2 and 3 and the treated filament is quickly cooled down by the cooling system 42.

Prior starting the treatment, the user selects the desired value of the selected parameter characterizing the functional mechanical properties of the treated filament e.g. the transformation strain and/or strength. From the interpolated dependence of the transformation strain and/or strength of the filament and changes of the electric resistance of the filament during the treatment, the desired value of the electric resistance of the treated filament is determined. The SMA filament is then exposed to the heat treatment by electric current on the apparatus shown in FIG. 3. During the treatment, the measuring and control unit 30 controls the supplied electric power P(t) in a feedback loop based on the desired and measured values of the electric resistance of the treated filament. If the electric resistance of the treated filament is smaller or larger than the desired value, the measuring and control unit 30 increases or decreases the supplied electric power P. If the filament prior the treatment had homogenous distribution of microstructure, following the treatment, it acquires functional mechanical properties characterized by the desired value of transformation strain and/or strength which are constant along the length of the filament with the limits given by the regulation. The electric resistance of the filament prior the treatment (measured between contacts 4 and 5) and after the treatment (measured between contacts 6 and 7) can be recorded and memorized by the measuring and control unit 30. The information on the deviation of the electric resistance from expected values and position along the length of the filament where this reading was recorded can be used for inspection of the homogeneity of the filaments.

### LIST OF MARKINGS USED IN FIGURES

2—first electrical contact of the electric current source for Joule heating
3—second electrical contact of the electric current source for Joule heating
4—first electrical contact for measurement of electrical resistance of untreated filament
5—second electrical contact for measurement of electrical resistance of untreated filament
6—first electrical contact for measurement of electrical resistance of treated filament
7—second electrical contact for measurement of electrical resistance of treated filament
10—feeding spool with driving unit with filament to be treated
15—SMA filament
20—taking spool with driving unit with treated filament
30—measuring and control unit
32—electric current source
34—filament tensile stress control element
38—system for control of the tensile stress or tensile strain in the filament
36—ultrasound source and evaluation unit
42—cooling system
62—ultrasound exciter
64—ultrasound sensor
66—noncontact temperature sensor
84—filament grip with electrical contact
85—filament grip with electrical contact
92—filament shaping element
111—tensile stress-strain curve of the filament at room temperature T=22° C. prior the heat treatment of continuous filament
112—tensile stress-strain curve of the filament at room temperature T=22° C. after the heat treatment of continuous filament for Tₚ=557.1° C.
113—tensile stress-strain curve of the filament at room temperature T=22° C. after the heat treatment of continuous filament for Tₚ=834.9° C.
121—tensile stress-strain curve of the filament at room temperature T=22° C. prior the heat treatment of discontinuous filament
122—tensile stress-strain curve of the filament at room temperature T=22° C. after the heat treatment of discontinuous filament for Tₚ=657.1° C.
123—tensile stress-strain curve of the filament at room temperature T=22° C. after the heat treatment of discontinuous filament for Tₚ=964.5° C.
130—filament shaping element
131—experimentally determined variation of the electric resistance of the filament during heat treatment of discontinuous filament with constant power P and exposition time tₐ=1 ms
132—experimentally determined variation of the electric resistance of the filament during heat treatment of discontinuous filament with constant power P and exposition time tₐ=6 ms
133—experimentally determined variation of the electric resistance of the filament during heat treatment of discontinuous filament with constant power P and exposition time tₐ=11 ms
134—experimentally determined variation of the electric resistance of the filament during heat treatment of discontinuous filament with constant power P and exposition time tₐ=16 ms
135—experimentally determined variation of the electric resistance of the filament during heat treatment of discontinuous filament with constant power P and exposition time tₐ=21 ms
141—tensile stress-strain curves of the filament at room temperature after heat treatment of discontinuous filament with constant power P and exposition time tₐ=1 ms
142—tensile stress-strain curves of the filament at room temperature after heat treatment of discontinuous filament with constant power P and exposition time tₐ=6 ms
143—tensile stress-strain curves of the filament at room temperature after heat treatment of discontinuous filament with constant power P and exposition time tₐ=11 ms
144—tensile stress-strain curves of the filament at room temperature after heat treatment of discontinuous filament with constant power P and exposition time tₐ=16 ms
145—tensile stress-strain curves of the filament at room temperature after heat treatment of discontinuous filament with constant power P and exposition time tₐ=21 ms
152—sense of rotation of filament shaping element
154—direction of the shift of the filament shaping element
300—connection between the measuring and control unit (30) and electric current source (32)
301—connection between the measuring and control unit (30) and feeding spool (10)
302—connection between the measuring and control unit (30) and taking spool (20)
303—connection between the measuring and control unit (30) and filament tensile stress control element (34)
304—connection between the measuring and control unit (30) and electrical contact (4)
305—connection between the measuring and control unit (30) and electrical contact (5)
306—connection between the measuring and control unit (30) and electrical contact (6)
307—connection between the measuring and control unit (30) and electrical contact (7)
314—connection between the noncontact temperature sensor (66) and measuring and control unit (30)
315—connection between the ultrasound source and signal processing unit (36) and measuring and control unit (30)
322—connection between the electric current source (32) and electrical contact (2)
323—connection between the electric current source (32) and electrical contact (3)
324—connection between the electric current source (32) and filament grip (84)
325—connection between the electric current source (32) and filament grip (85)
361—connection between the ultrasound source and signal processing unit (36) and ultrasound exciter (62)
362—connection between the ultrasound source and signal processing unit (36) and ultrasound sensor (64)
402—rigid frame supporting the system for control of the tensile stress or tensile strain in the filament (38)

1. A method of heat treatment of SMA filaments, particularly NiTi, allowing for setting their functional mechanical properties, particularly to transformation strain and/or strength, characterized in that,
a sample of the filament, the functional mechanical properties of which, particularly transformation strain and/or strength, are to be set is taken;
a dependence between transformation strain and/or strength of this filament and maximum filament temperature achieved by Joule heating under selected tensile stress is established;
maximum filament temperature needed to set the required transformation strain and/or strength is determined from this dependence;
electric power needed to reach this maximum filament temperature by Joule heating is calculated;
the filament is subsequently exposed to electric current for a time corresponding to the calculated electric power while applying the selected tensile stress.

2. A method of heat treatment of SMA filaments, particularly NiTi, allowing for setting their functional mechanical properties, particularly to transformation strain and/or strength, characterized in that,
a sample of the filament, the functional mechanical properties of which, particularly transformation strain and/or strength, are to be set is taken;
a dependence between transformation strain and/or strength of this filament and maximum filament temperature achieved by Joule heating under selected tensile stress is established;
maximum filament temperature needed to set the required transformation strain and/or strength is determined from this dependence;
the filament is subsequently exposed to electric current controlled in a feedback loop so that the measured temperature of the SMA filament corresponds to the set value while applying the selected tensile stress.

3. A method of heat treatment of SMA filaments, particularly NiTi, allowing for setting their functional mechanical properties, particularly to transformation strain and/or strength, characterized in that,
a sample of the filament, the functional mechanical properties of which, particularly transformation strain and/or strength, are to be set is taken;
a dependence between transformation strain and/or strength of this filament and change of the electric resistance of the filament before and after treatment under controlled tensile stress is established;
the change of the electric resistance of the filament before and after treatment corresponding to the desired transformation strain and/or strength is determined from this dependence;
the filament is subsequently exposed to electric current controlled in a feedback loop so that the change of the electric resistance of the filament before and after treatment corresponds to the set value while applying the selected tensile stress.

4. The method according to claim 1, characterized in that the employed tensile stress in the filament is larger than 600 MPa and simultaneously the maximum filament temperature reached in the treatment is smaller than 300° C.

5. The method according to claim 1, characterized in that the electric power and/or tensile stress acting on the filament varies in time.

6. The method according to claim 1, characterized in that the time for which the electric current acts on the filament is smaller than 100 ms.

7. An apparatus for application of the heat treatment of continuous SMA filaments allowing for setting their functional mechanical properties, according to claim 1, characterized in that,
the said apparatus consists at least from the filament supply unit and the filament taking unit, at least two contacts (2), (3) establishing electrical contact with spooled filament (15), electric current source (32) and filament tensile stress control element (34), where the electric current source (32) is linked to the said contacts by lead wires (322) a (323) and the filament (15) is guided from the filament supply unit over the contacts (2), (3) and the filament tensile stress control element (34) to the filament taking unit, and the filament between the contacts (2) a (3) is beneficially placed in protecting inert gas atmosphere.

8. An apparatus for application of the heat treatment of SMA filaments allowing for setting their functional mechanical properties, according to claim 2, characterized in that,
the filament supply unit is the feeding spool (10) and the filament taking unit is the taking spool (20) with driving units, and the apparatus further contains a temperature sensor (66) placed between two electrical contacts (2), (3), measuring and control unit (30) to which the temperature sensor (66), filament tensile stress control element (34) and electric current source (32) are linked, the measuring and control unit (30) is beneficially connected to the driving units of the feeding spool (10) and taking spool (20).

9. An apparatus for application of the heat treatment of SMA filaments allowing for setting their functional mechanical properties, according to claim 3, characterized in that,
the filament supply unit is the feeding spool (10) and the filament taking unit is the taking spool (20) with driving units, and the apparatus further contains two additional contacts (4) and (5) placed before the contacts (2) and (3) establishing electrical contacts with the spooled filament (15) and two additional contacts (6) and (7) placed after the contacts (2) and (3) establishing electrical contacts with the spooled filament (15), measuring and control unit (30) to which the electrical contacts (4),(5),(6),(7), filament tensile stress control element (34) and electric current source (32) are linked, the measuring and control unit (30) is beneficially connected to the driving units of the feeding spool (10) and taking spool (20) and the apparatus also beneficially contains a cooling system (42).

10. An apparatus for application of the heat treatment of continuous SMA filaments allowing for setting their functional mechanical properties, according to claim 7, characterized in that,
the filament (15) is guided between the contacts (2) and (3) connected to electric current source (32) through the filament shaping element (130), for example an electrically nonconductive screw.

11. An apparatus for application of the heat treatment of discontinuous SMA filaments allowing for setting their functional mechanical properties, according to claim 1, characterized in that,
the said apparatus consists at least of two conducting grips (84) and (85) for the filament (15), electric current source (32), system for control of the tensile stress or tensile strain in the filament (38) connected to one of the filament grips or directly to the filament (15), electric current source (32) is connected with filament grips (84) and (85) and the apparatus beneficially contains measuring and control unit (30) connected with the electric current source (32).

12. An apparatus for application of the heat treatment of discontinuous SMA filaments allowing for setting their functional mechanical properties, according to the claim 11, characterized in that,
the apparatus further contains shaping element (92), for example configurable set of pins, textile or composite structure, and the filament (15) is guided between the filament grips (84) and (85) through an additional shaping element (92).

13. A method of the inspection of the homogeneity of functional mechanical properties of SMA filaments, particularly to transformation strain and/or strength of NiTi continuous filaments, characterized in that,
at least of the one of the following quantities of the treated filament: electrical resistance, temperature, characteristics of the passing through ultrasonic signal, for example attenuation, is measured, the filament homogeneity is subsequently evaluated as deviation of the measured value from the expected value of that quantity, for example average value, a record of inhomogeneity is assigned to the position in the filament, where it was detected based on the magnitude of this deviation and this record is memorized by the measuring and control unit, optionally including the record of the position of the detected inhomogeneity.

14. An apparatus for application of the heat treatment and/or inspection of homogeneity of continuous SMA filaments, particularly NiTi, allowing for setting of their functional mechanical properties, particularly to transformation strain and/or strength, according to claim 13, characterized in that,
the said apparatus further contains at least one of the following components, at least two contacts (6) and (7) establishing electrical contacts with the spooled filament (15) which are connected to the measuring and control unit (30), or ultrasound source and evaluation unit (36) linked to the ultrasound exciter (62) and to the ultrasound sensor (64) and to the measuring and control unit (30), or temperature sensor (66) connected to the measuring and control unit (30).

15. An apparatus for application of the heat treatment of SMA filaments allowing for setting their functional mechanical properties, according to claim 7, characterized in that,
the filament supply unit is the feeding spool (10) and the filament taking unit is the taking spool (20) with driving units, and the apparatus further contains a temperature sensor (66) placed between two electrical contacts (2), (3), measuring and control unit (30) to which the temperature sensor (66), filament tensile stress control element (34) and electric current source (32) are linked, the measuring and control unit (30) is beneficially connected to the driving units of the feeding spool (10) and taking spool (20).

16. An apparatus for application of the heat treatment of SMA filaments allowing for setting their functional mechanical properties, according to claim 7, characterized in that,
the filament supply unit is the feeding spool (10) and the filament taking unit is the taking spool (20) with driving units, and the apparatus further contains two additional contacts (4) and (5) placed before the contacts (2) and (3) establishing electrical contacts with the spooled filament (15) and two additional contacts (6) and (7) placed after the contacts (2) and (3) establishing electrical contacts with the spooled filament (15), measuring and control unit (30) to which the electrical contacts (4),(5),(6),(7), filament tensile stress control element (34) and electric current source (32) are linked, the measuring and control unit (30) is beneficially connected to the driving units of the feeding spool (10) and taking spool (20) and the apparatus also beneficially contains a cooling system (42).

17. An apparatus for application of the heat treatment and/or inspection of homogeneity of continuous SMA filaments, particularly NiTi, allowing for setting of their functional mechanical properties, particularly to transformation strain and/or strength, according to claim 7, characterized in that,
the said apparatus further contains at least one of the following components, at least two contacts (6) and (7) establishing electrical contacts with the spooled filament (15) which are connected to the measuring and control unit (30), or ultrasound source and evaluation unit (36) linked to the ultrasound exciter (62) and to the ultrasound sensor (64) and to the measuring and control unit (30), or temperature sensor (66) connected to the measuring and control unit (30).
